(19) United States
(12) Patent Application Publication
(10) Pub. No.: US 2023/0298967 A1
(43) Pub. Date: Sep. 21, 2023

(54) LIQUID COOLING JACKET AND COOLING DEVICE

(71) Applicant: Nidec Corporation, Kyoto (JP)

(72) Inventors: Yuta HORI, Kyoto (JP); Kazuhiro NISHIKAWA, Kyoto (JP); Kengo INOUE, Kyoto (JP)

(21) Appl. No.: 18/119,865

(22) Filed: Mar. 10, 2023

(30) Foreign Application Priority Data
Mar. 15, 2022 (JP) 2022-040291

(51) Int. Cl. H01L 23/473

(52) U.S. Cl. CPC H01L 23/473

(57) ABSTRACT

A liquid cooling jacket includes a refrigerant flow path including a heat radiating portion on one side, a bottom surface located on the other side of the refrigerant flow path, and a protrusion protruding from the bottom surface toward one side. A first inclined portion is provided on the one side which is a downstream side of the protrusion. A first-direction length of the first inclined portion is longer than a height of the protrusion at a first-direction other end of the first inclined portion.

### CROSS-REFERENCE TO RELATED APPLICATIONS

The present application claims priority under 35 U.S.C. § 119 to Japanese Patent Application No. 2022-040291, filed on Mar. 15, 2022, the entire contents of which are hereby incorporated herein by reference.

### 1. FIELD OF THE INVENTION

The present disclosure relates to a liquid cooling jacket.

### 2. BACKGROUND

Conventionally, a water jacket used for water cooling is known. A heat radiating member is accommodated in the water jacket. The inside of the water jacket serves as a flow path of cooling water, and a heating element is water-cooled via the heat radiating member.

In this case, the water jacket is required to suppress a pressure loss in addition to the improvement of cooling performance. When the pressure loss increases, a desired flow rate may not be secured depending on the performance of a pump for circulating cooling water. Alternatively, in order to secure a desired flow rate, it is necessary to employ a large, expensive pump.

### SUMMARY

A liquid cooling jacket according to an example embodiment of the present disclosure includes, with a direction along a direction in which a refrigerant flows being defined as a first direction, a direction perpendicular or substantially perpendicular to the first direction being defined as a second direction, and a direction perpendicular or substantially perpendicular to the first direction and the second direction being defined as a third direction, a refrigerant flow path including a width in the second direction and a heat radiating portion on one side in the third direction, a bottom surface located on the other side of the refrigerant flow path in the third direction, and one protrusion protruding from the bottom surface toward the one side in the third direction or a plurality of protrusions arranged in the first direction. A first inclined portion inclined to one side in the first direction and the other side in the third direction is provided on the one side in the first direction which is a downstream side of at least one of the plurality of protrusions. A first-direction length of the first inclined portion is longer than a third-direction height of the at least one protrusion at a first-direction other end of the first inclined portion.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is an exploded perspective view of a cooling device according to a first example embodiment of the present disclosure.

FIG. 2 is a side cross-sectional view of the cooling device according to the first example embodiment.

FIG. 3 is a side cross-sectional view illustrating the configuration of a protrusion according to the first example embodiment.

FIG. 4 is a side cross-sectional view illustrating the configuration of a protrusion according to a comparative example.

FIG. 5 is a side cross-sectional view illustrating the configuration of a protrusion according to a modification of the first example embodiment.

FIG. 6 is a side cross-sectional view illustrating the configuration of a protrusion according to a second example embodiment of the present disclosure.

FIG. 7 is a side cross-sectional view of a cooling device according to a third example embodiment of the present disclosure.

FIG. 8 is a side cross-sectional view illustrating the configuration of a protrusion according to the third example embodiment.

FIG. 9 is a view illustrating an example of a simulation result by a model of a cooling device in a case where various protrusions are used.

FIG. 10 is a partial side cross-sectional view of a cooling device according to a fourth example embodiment of the present disclosure.

FIG. 11 is a partial side cross-sectional view of a cooling device according to a fifth example embodiment of the present disclosure.

### DETAILED DESCRIPTION

Hereinafter, example embodiments of the present disclosure will be described with reference to the drawings.

In the drawings, with the first direction as an X direction, X1 indicates one side in the first direction, and X2 indicates the other side in the first direction. The first direction is a direction along a direction F in which a refrigerant W flows, and the downstream side is indicated by F1 and the upstream side is indicated by F2. The downstream side F1 is one side in the first direction, and the upstream side F2 is the other side in the first direction. With the second direction orthogonal to the first direction as a Y direction, Y1 indicates one side in the second direction, and Y2 indicates the other side in the second direction. With the third direction orthogonal to the first direction and the second direction as a Z direction, Z1 indicates one side in the third direction, and Z2 indicates the other side in the third direction. Note that the above-described “orthogonal” also includes intersection at an angle slightly shifted from 90°. Each of the above-described directions does not limit a direction when a cooling device 1 is incorporated in various devices.

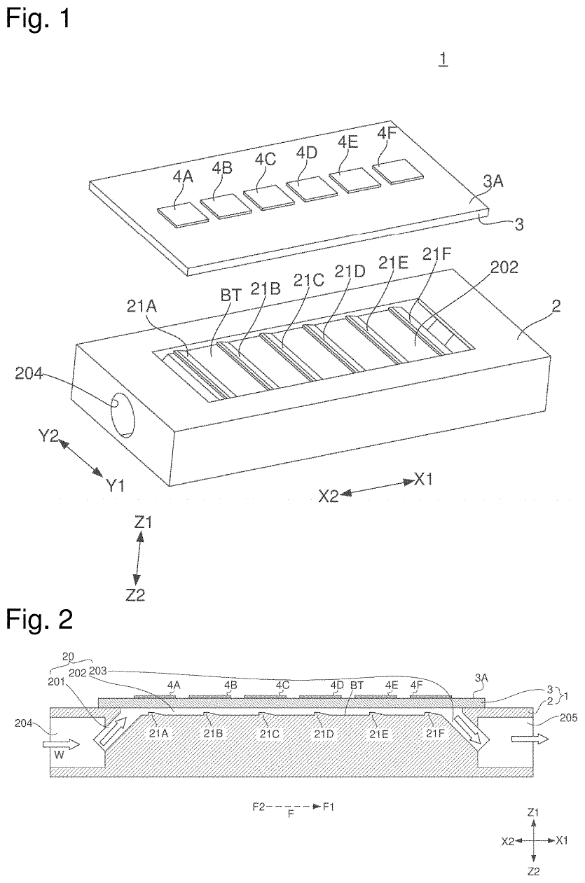

FIG. 1 is an exploded perspective view of the cooling device 1 according to a first example embodiment. FIG. 2 is a side cross-sectional view of the cooling device 1 according to the first example embodiment. FIG. 2 is a view of a state cut along a cross-section orthogonal to the second direction as viewed in the second direction.

The cooling device 1 includes a liquid cooling jacket 2 and a heat radiating portion 3. The cooling device 1 is a device that cools a plurality of heating elements 4A, 4B, 4C, 4D, 4E, and 4F (to be referred to as the heating element 4A and the like hereinafter) with a refrigerant W. The refrigerant W is liquid such as water. That is, the cooling device 1 performs liquid cooling such as water cooling. The number of heating elements may be a plural number other than six or may be singular.

The liquid cooling jacket 2 has a rectangular parallelepiped shape having sides extending in the first direction, the second direction, and the third direction. The liquid cooling jacket 2 is, for example, a die-cast product made from a metal such as aluminum. The liquid cooling jacket 2 has a flow path for allowing the refrigerant W to flow therein.

More specifically, the liquid cooling jacket 2 includes a refrigerant flow path 20, an inlet flow path 204, and an outlet flow path 205. The inlet flow path 204 is arranged in the first-direction other end portion of the liquid cooling jacket 2 and has a columnar shape extending in the first direction.

The refrigerant flow path 20 includes a first flow path 201, a second flow path 202, and a third flow path 203. The first flow path 201 has a width in the second direction and is inclined to one side in the first direction and one side in the third direction. The first-direction other end portion of the first flow path 201 is connected to first-direction one end portion of the inlet flow path 204. The second flow path 202 has a width in the second direction and extends in the first direction. The first-direction other end portion of the second flow path 202 is connected to first-direction one end portion of the first flow path 201. The third flow path 203 has a width in the second direction and is inclined to one side in the first direction and the other side in the third direction. First-direction one end portion of the second flow path 202 is connected to the first-direction other end portion of the third flow path 203.

The outlet flow path 205 is arranged in first-direction one end portion of the liquid cooling jacket 2 and has a columnar shape extending in the first direction. First-direction one end portion of the third flow path 203 is connected to the first-direction other end portion of the outlet flow path 205.

In this manner, the refrigerant W flowing into the inlet flow path 204 flows into the first flow path 201 and flows to one side in the first direction and one side in the third direction in the first flow path 201, flows into the second flow path 202 and flows to one side in the first direction in the second flow path 202, flows into the third flow path 203 and flows to one side in the first direction and the other side in the third direction in the third flow path 203, and flows into the outlet flow path 205 and is discharged to the outside of the liquid cooling jacket 2.

Here, the heat radiating portion 3 is a rectangular parallelepiped flat plate having sides extending in the first direction, the second direction, and the third direction, and has thickness in the third direction. The heat radiating portion 3 is, for example, a copper plate. In a state where the heat radiating portion 3 is not attached to the liquid cooling jacket 2, one side of each of the first flow path 201, the second flow path 202, and the third flow path 203 in the third direction is exposed to the outside. The heat radiating portion 3 is attached to the liquid cooling jacket 2 by being arranged on one side of the first flow path 201, the second flow path 202, and the third flow path 203 in the third direction. In this manner, one side of each of the first flow path 201, the second flow path 202, and the third flow path 203 in the third direction is not exposed to the outside.

That is, the liquid cooling jacket 2 has a width in the second direction and has the refrigerant flow path 20 in which the heat radiating portion 3 can be arranged on one side in the third direction.

The heating elements 4A and the like are arranged side by side in the first direction. The heating elements 4A and the like are in direct or indirect contact with a third-direction one side surface 3A of the heat radiating portion 3. Heat generated from the heating elements 4A and the like is transmitted to the refrigerant W flowing through the second flow path 202 via the heat radiating portion 3, so that the heating elements 4A and the like are cooled.

The liquid cooling jacket 2 has a plurality of protrusions 21A, 21B, 21C, 21D, 21E, and 21F (to be referred to as the protrusion 21A and the like hereinafter). The number of protrusions is six in accordance with the number of the heating elements 4A and the like. Note that the number of protrusions may be a plural number other than six or may be singular.

The protrusions 21A and the like protrude to one side in the third direction from a bottom surface portion BT arranged on the other side in the third direction of the second flow path 202. That is, the liquid cooling jacket 2 includes a bottom surface portion BT of the refrigerant flow path 20 which is located on the other side in the third direction and one protrusion 21A protruding from the bottom surface portion BT toward one side in the third direction or a plurality of protrusions 21A arranged in the first direction and the like.

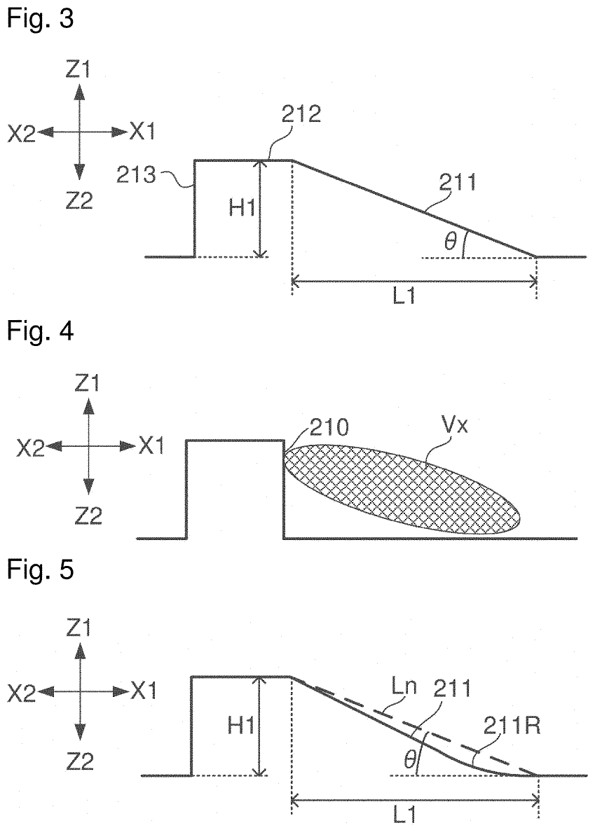

In this case, FIG. 3 is an enlarged side cross-sectional view of each of the protrusion 21A and the like. As illustrated in FIG. 3, each of the protrusion 21A and the like include a first inclined portion 211, a top surface portion 212, and an upstream wall surface portion 213. The first inclined portion 211 is provided on one side in the first direction which is the downstream side of each of the protrusion 21A and the like and is inclined to one side in the first direction and the other side in the third direction. That is, the first inclined portion 211 inclined to one side in the first direction and the other side in the third direction is provided on one side in the first direction which is the downstream side of at least one protrusion 21A and the like.

The top surface portion 212 is a plane extending linearly in the first direction. First-direction one end of the top surface portion 212 is connected to the other side of the first inclined portion 211 in the first direction. The upstream wall surface portion 213 is a plane extending perpendicularly with respect to the bottom surface portion BT from the first-direction other end of the top surface portion 212 to the other side in the third direction.

In this case, FIG. 4 illustrates an example of a protrusion having a downstream wall surface portion 210 extending perpendicularly with respect to the bottom surface portion BT in the third direction instead of the first inclined portion 211 on one side in the first direction. Providing the protrusion will narrow the gap between the protrusion and the heat radiating portion 3, increase the flow velocity of the refrigerant W, and easily generate turbulence, thereby improving the cooling performance for cooling the heating element 4A and the like. However, if the first inclined portion 211 is not provided, a vortex Vx is generated on the downstream side of the protrusion, and the pressure loss increases. The downstream wall surface portion 210 may be referred to as a first-direction one side end surface.

In contrast to this, in the case of the protrusion 21A and the like according to the present example embodiment, as illustrated in FIG. 3, a first-direction length L1 of the first inclined portion 211 is longer than a third-direction height H1 of the protrusion 21A and the like at the first-direction other end of the first inclined portion 211. As a result, the region where a vortex is formed on the downstream side of the protrusion can be covered with the first inclined portion 211, the formation of the vortex can be suppressed, and the pressure loss is suppressed. Accordingly, it is possible to achieve both the securing of the cooling performance and the suppression of the pressure loss by the protrusion 21A and the like.

In other words, an angle θ of a straight line extending from first-direction one end of the first inclined portion 211 to the first-direction other end of the first inclined portion 211 with respect to the bottom surface portion BT is 45° or less (FIG. 3).

The protrusion 21A and the like each may have a configuration as illustrated in FIG. 5. FIG. 5 is a side cross-sectional view of each of the protrusion 21A and the like according to a modification. In the case of the protrusion 21A and the like illustrated in FIG. 5, the first inclined portion 211 has a curvature 211R at first-direction one end portion. Even in the case of the first inclined portion 211, the first-direction length L1 of the first inclined portion 211 is longer than the third-direction height H1 of the protrusion 21A and the like at the first-direction other end of the first inclined portion 211. The angle θ of a straight line Ln extending from first-direction one end of the first inclined portion 211 to the first-direction other end of the first inclined portion 211 with respect to the bottom surface portion BT is 45° or less.

The cooling device 1 according to the present example embodiment includes the liquid cooling jacket 2 and the heat radiating portion 3 having a flat plate shape that is arranged on one side in the third direction of the refrigerant flow path 20, spreads in the first direction and the second direction, and has thickness in the third direction. This makes it possible to achieve both the securing of the cooling performance and the suppression of pressure loss by the protrusion 21A and the like while reducing the cost without providing fins such as pin fins for the heat radiating portion.

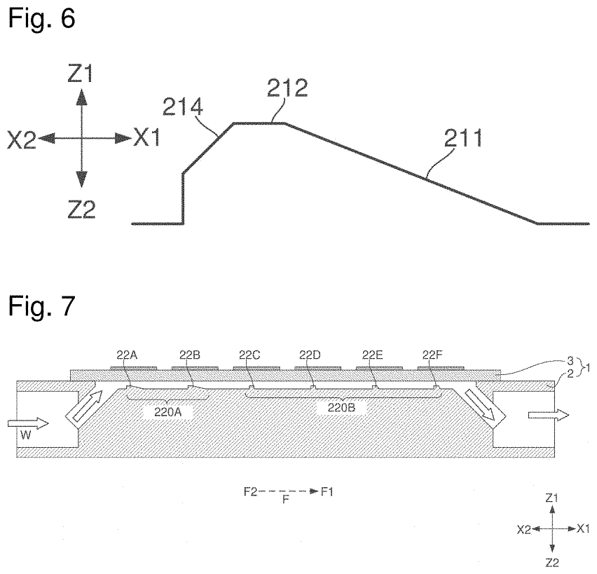

FIG. 6 is a side cross-sectional view illustrating the configuration of each of a protrusion 21A and the like according to a second example embodiment. Each of the protrusion 21A and the like illustrated in FIG. 6 has a C surface 214 unlike the first example embodiment. The C surface 214 is connected to the first-direction other end of the top surface portion 212 and is inclined to the other side in the first direction and the other side in the third direction. That is, the C surface 214 is provided on the other side of the at least one protrusion 21A and the like in the first direction. Providing the C surface 214 in addition to the first inclined portion 211 in this manner can further suppress the pressure loss.

FIG. 7 is a side cross-sectional view of a cooling device 1 according to a third example embodiment. In the cooling device 1 illustrated in FIG. 7, a liquid cooling jacket 2 is provided with protrusions 22A, 22B, 22C, 22D, 22E, and 22F. The protrusions 22A and 22B are arranged side by side in the first direction on the upstream side. The protrusions 22C and 22D are arranged side by side in the first direction at the center. The protrusions 22E and 22F are arranged side by side in the first direction on the downstream side. As described later, the protrusions 22A and 22B, 22C and 22D, and 22E and 22F have different shapes.

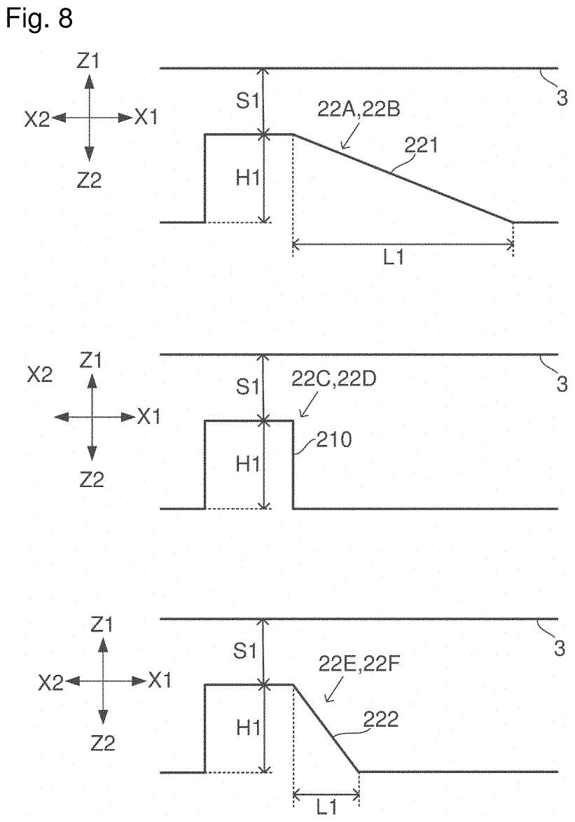

FIG. 8 is a side cross-sectional view illustrating the configuration of each of the protrusions 22A and 22B, 22C and 22D, and 22E and 22F.

The protrusions 22A and 22B each have a first inclined portion 221 as in the first example embodiment. As described above, a first-direction length L1 of the first inclined portion 211 is longer than a third-direction height H1 of the protrusion 21A and the like at the first-direction other end of the first inclined portion 211. The protrusions 22A and 22B having the first inclined portions 221 described above can be referred to as long tapered protrusions.

The protrusions 22C and 22D each have a downstream wall surface portion 210 extending perpendicularly with respect to the bottom surface portion BT in the third direction, similarly to the configuration described above with reference to FIG. 4. The protrusions 22C and 22D described above can be referred to as non-tapered protrusions.

The protrusions 22E and 22F each have a second inclined portion 222. The first-direction length L1 of the second inclined portion 222 is shorter than the third-direction height H1 of the protrusions 22E and 22F at the first-direction other end of the second inclined portion 222. The protrusions 22E and 22F each having the second inclined portion 222 described above can be referred to as short tapered protrusions.

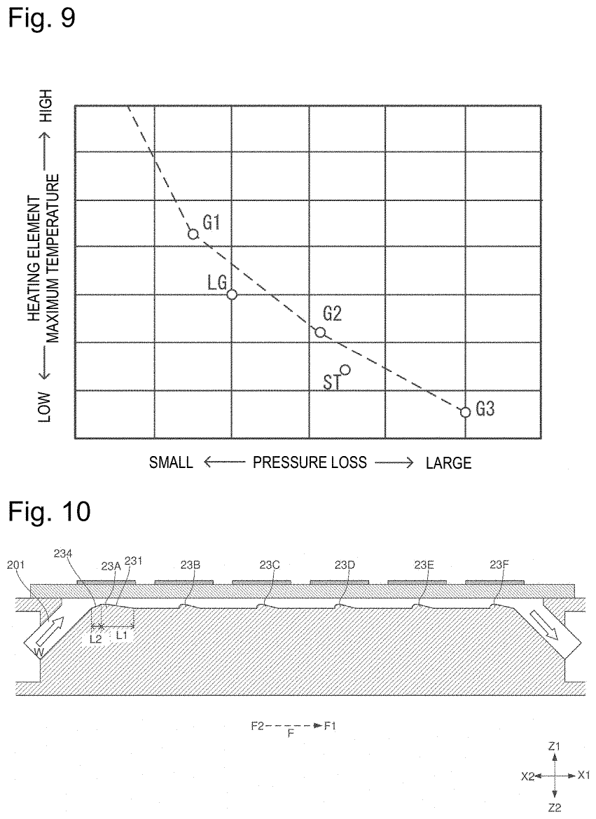

In this case, FIG. 9 illustrates an example of a simulation result by a model of the cooling device 1 in a case where various protrusions are used. Referring to FIG. 9, the horizontal axis represents the pressure loss, and the vertical axis represents the maximum temperature of the heating element.

Referring to FIG. 9, simulation results when the third direction gap (gap) between the protrusion and the heat radiating portion 3 is changed at the non-tapered protrusion are plotted as G1, G2, and G3. The gap satisfies G1>G2>G3. The broken line in FIG. 9 indicates an approximate straight line when the gap is changed. As described above, as the gap is narrower, the pressure loss increases, but the cooling performance is improved.

Referring to FIG. 9, assuming that the condition of the gap is the same as G2, simulation results in the case of using the long tapered type protrusion and the short tapered type protrusion are illustrated as LG and ST, respectively. As described above, the heating element temperature is LG>G2>ST, and the pressure loss is LG<G2<ST. Therefore, the pressure loss can be most suppressed with the long tapered type, and the cooling performance can be most improved with the short tapered type.

Accordingly, in the present example embodiment, as shown in FIG. 7, the long tapered type protrusions 22A and 22B are used on the upstream side where the temperature of the refrigerant W is low and the need for cooling performance is low, the short tapered type protrusions 22E and 22F are used on the downstream side where the temperature of the refrigerant W is high and the need for cooling performance is high, and the non-tapered type protrusions 22C and 22D are used at the center. As described above, the shape of the protrusion can be appropriately selected according to the necessary cooling performance, and both the securing of the cooling performance and the suppression of the pressure loss can be achieved. In the present example embodiment, the third-direction height H1 is made constant at the protrusion 22A and the like, and the gap S1 between the protrusion 22A and the like and the heat radiating portion 3 is made constant (FIG. 8).

In this case, as illustrated in FIG. 7, the upstream protrusion 220A includes the protrusions 22A and 22B, and the downstream protrusion 220B includes the protrusions 22C, 22D, 22E, and 22F. That is, the plurality of protrusion 22A and the like arranged in the first direction include at least one upstream protrusion 220A arranged on the other side in the first direction and at least one downstream protrusion 220B arranged on one side in the first direction. Of the upstream protrusion 220A and the downstream protrusion 220B, at least the upstream protrusion 220A is provided with the first inclined portion 221. This makes it possible to prioritize the reduction of the pressure loss over the cooling performance on the upstream side where the temperature of the refrigerant W is low and the cooling performance is relatively unnecessary.

Furthermore, the second inclined portion 222 inclined to one side in the first direction and the other side in the third direction is provided on one side in the first direction of at least one of the first protrusions 22E and 22F included in the downstream protrusion 220B. The first-direction length L1 of the second inclined portion 222 is shorter than the third-direction height H1 of the first protrusions 22E and 22F at the first-direction other end of the second inclined portion 222. As a result, the first inclined portion is provided on the upstream side where the cooling performance is relatively unnecessary to prioritize the reduction of the pressure loss over the cooling performance, and the second inclined portion is provided on the downstream side where the cooling performance is relatively necessary to prioritize the cooling performance over the pressure loss. This makes it possible to suppress an increase in pressure loss while ensuring the cooling performance.

Furthermore, at least one of the second protrusions 22C and 22D included in the downstream protrusion 220B is disposed on the other side in the first direction with respect to the first protrusions 22E and 22F. The first-direction one side end surface 210 (FIG. 8) of each of the second protrusions 22C and 22D extends perpendicular with respect to the bottom surface portion BT in the third direction. As a result, the balance between the cooling performance and the pressure loss can be optimized on each of the upstream side, the center, and the downstream side.

FIG. 10 is a side cross-sectional view of a cooling device 1 according to a fourth example embodiment. In the cooling device 1 illustrated in FIG. 10, protrusions 23A, 23B, 23C, 23D, 23E, and 23F (to be referred to as the protrusion 23A and the like) are provided in a liquid cooling jacket 2.

Each of the protrusions 23A includes a first inclined portion 231 on one side in the first direction and is configured as a long tapered protrusion. However, in the present example embodiment, the first inclined portion 231 of the protrusion 23A disposed on the most upstream side has a first-direction length L1 longer than the first inclined portion 231 of each of the other protrusions 23B to 23F. That is, at least one protrusion 23A and the like include a plurality of protrusions, and the first-direction length L1 of the first inclined portion 231 of the protrusion 23A arranged on the other side in the first direction is the longest. As a result, as shown in FIG. 10, when a first flow path 201 that guides a refrigerant W so as to obliquely rush into the protrusion 23A disposed on the most upstream side is provided, the pressure loss can be further suppressed.

Each of the protrusion 23A and the like has a C surface 234 on the other side in the first direction. However, in the present example embodiment, the C surface 234 of the protrusion 23A disposed on the most upstream side has a first-direction length L2 longer than the C surface 234 of each of the other protrusions 23B to 23F. That is, the at least one protrusion 23A and the like include a plurality of protrusions. The first-direction length L2 of the C surface 234 of the protrusion 23A on the other side in the first direction is the longest. As a result, as shown in FIG. 10, when a first flow path 201 that guides a refrigerant W so as to obliquely rush into the protrusion 23A disposed on the most upstream side is provided, the pressure loss can be further suppressed.

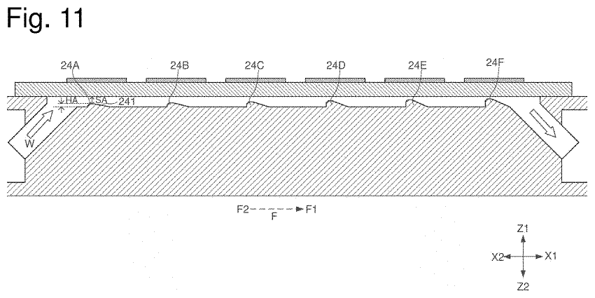

FIG. 11 is a side cross-sectional view of a cooling device 1 according to a fifth example embodiment. In the cooling device 1 illustrated in FIG. 11, a liquid cooling jacket 2 is provided with protrusions 24A, 24B, 24C, 24D, 24E, and 24F (to be referred to as the protrusion 24A and the like hereinafter).

Each of the protrusion 24A and the like includes a first inclined portion 241. The first-direction lengths of the first inclined portions 241 of the protrusion 24A and the like are the same. A third-direction height HA of each of the protrusions 24A to 24E at the first-direction other end of the first inclined portion 241 of each of the protrusions 24A to 24E gradually increases toward the downstream side. Therefore, a third direction gap SA between each of the protrusions 24A to 24F and a heat radiating portion 3 gradually narrows toward the downstream side. This makes it possible to prioritize the pressure loss out of the cooling performance and the pressure loss on the upstream side where the cooling performance is relatively unnecessary and to prioritize the cooling performance out of the cooling performance and the pressure loss on the downstream side where the cooling performance is relatively necessary.

That is, at least one protrusion 24A and the like include a plurality of protrusions, and the third-direction height of each of the protrusion 24A and the like at the first-direction other end of the first inclined portion 241 increases toward one side in the first direction. As a result, the balance between the cooling performance and the pressure loss can be made appropriate for each position in the first direction. The third-direction height HA of a part of each of the protrusion 24A and the like may be constant.

The present disclosure is not limited to the configuration of FIG. 11, and the third direction gap between the protrusion and the heat radiating portion 3 may be narrowed for each protrusion adjacent in the first direction. That is, the third direction gap may be gradually narrowed toward one side in the first direction.

The example embodiments of the present disclosure have been described above. Note that the scope of the present disclosure is not limited to the above example embodiments. The present disclosure can be implemented by making various changes to the above-described example embodiments without departing from the gist of the disclosure. The matters described in the above example embodiments can be optionally combined together, as appropriate, as long as there is no inconsistency.

For example, the heat radiating portion is not limited to a metal plate, and may be a vapor chamber or a heat pipe.

The present disclosure can be used for cooling various heating elements.

Features of the above-described example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A liquid cooling jacket comprising, with a direction along a direction in which a refrigerant flows being defined as a first direction, a direction perpendicular or substantially perpendicular to the first direction being defined as a second direction, and a direction perpendicular or substantially perpendicular to the first direction and the second direction being defined as a third direction:
a refrigerant flow path including a width in the second direction and a heat radiating portion on one side in the third direction;
a bottom surface located on the other side of the refrigerant flow path in the third direction; and
at least one protrusion protruding from the bottom surface toward the one side in the third direction or a plurality of protrusions arranged in the first direction; wherein
a first inclined portion inclined to one side in the first direction and the other side in the third direction is provided on the one side in the first direction which is a downstream side of at least one of the protrusions; and
a first-direction length of the first inclined portion is longer than a third-direction height of the protrusion at a first-direction other end of the first inclined portion.

2. The liquid cooling jacket according to claim 1, wherein an angle of a straight line extending from a first-direction one end of the first inclined portion to the first-direction other end of the first inclined portion with respect to the bottom surface is not more than about 45°.

3. The liquid cooling jacket according to claim 1, wherein a C surface is provided on the other side of the at least one protrusion in the first direction.

4. The liquid cooling jacket according to claim 3, wherein
the at least one protrusion includes a plurality of protrusions; and
a first-direction length of the C surface is longest at the protrusion located closest to the other side in the first direction.

5. The liquid cooling jacket according to claim 1, wherein
the plurality of protrusions arranged in the first direction include at least one upstream protrusion arranged on the other side in the first direction and at least one downstream protrusion arranged on the one side in the first direction; and
the first inclined portion is provided on at least the upstream protrusion out of the upstream protrusion and the downstream protrusion.

6. The liquid cooling jacket according to claim 5, wherein
a second inclined portion inclined to the one side in the first direction and the other side in the third direction is provided on the one side of at least one first protrusion included in the downstream protrusion in the first direction; and
a first-direction length of the second inclined portion is shorter than a third-direction height of the first protrusion at the first-direction other end of the second inclined portion.

7. The liquid cooling jacket according to claim 6, wherein
at least one second protrusion included in the downstream protrusion is provided on the other side in the first direction with respect to the first protrusion; and
a first-direction one side end surface of the second protrusion extends perpendicularly or substantially perpendicularly to the bottom surface in the third direction.

8. The liquid cooling jacket according to claim 1, wherein
the at least one protrusion includes a plurality of protrusions; and
a first-direction length of the first inclined portion is longest at the protrusion closest to the other side in the first direction.

9. The liquid cooling jacket according to claim 1, wherein
the at least one protrusion includes a plurality of protrusions; and
a third-direction height of the protrusion at the first-direction other end of the first inclined portion increases toward the one side in the first direction.

10. A cooling device comprising:
the liquid cooling jacket according to claim 1; and
a heat radiator with a flat plate shape and located on the one side in the third direction of the refrigerant flow path, extending in the first direction and the second direction, and having a thickness in the third direction.
